(19) United States
(12) Patent Application Publication
(10) Pub. No.: US 2006/0163711 A1
(43) Pub. Date: Jul. 27, 2006

(54) Method to form an electronic device

(76) Inventor: Timothy J. Roels, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/042,227

(22) Filed: Jan. 24, 2005

(51) Int. Cl. H01L 23/02

(52) U.S. Cl. 257/680

(57) ABSTRACT

An electronic device includes a substrate and at least one electronic component formed on the substrate. The device also includes a lid coupled to the substrate, in which the lid at least partially covers the electronic component. The lid is partially trenched using one or more micro-blasting processes.

### BACKGROUND OF THE INVENTION

Electronic devices may be formed from a wafer, and a plurality of devices may be packaged on a single wafer prior to singulation into individual devices. Methods of packaging and/or singulating devices may vary, and one or more methods of packaging and/or singulation may have particular advantages. For example, particular methods of singulation may result in the formation of debris on the devices, may cause physical damage to the devices, may not be particularly adaptable to varying singulation patterns, and/or may affect the performance of the singulated devices.

### BRIEF DESCRIPTION OF THE DRAWINGS

Subject matter is particularly pointed out and distinctly claimed in the concluding portion of the specification. Claimed subject matter, however, both as to organization and method of operation, together with features, and advantages thereof, may best be understood by reference of the following detailed description when read with the accompanying drawings in which:

FIG. 1 is a sectional cut-away view of a MEMS device package in accordance with at least one embodiment;

FIG. 2a is a non-singulated lid in accordance with at least one embodiment;

FIG. 2b is a sectional cut-away view of a non-singulated lid in accordance with at least one embodiment;

FIG. 3 is a sectional cut-away view of a plurality of non-singulated MEMS device packages in accordance with at least one embodiment;

FIG. 4 is an illustration of a singulation operation, in accordance with at least one embodiment;

FIGS. 5a-5d are illustrations of multiple stages of formation of features in a lid in accordance with at least one embodiment; and

FIG. 6 is a flowchart illustrating an embodiment of a method for forming an electronic device.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail so as not to obscure claimed subject matter.

Micro-electro-mechanical systems (MEMS) may refer generally to devices having one or more electrical and/or mechanical components that may typically be formed into a packaged device. Devices such as these may include light engines, such as used in projector systems, actuators, pressure sensors, and/or optical detectors. Devices such as these may be formed or packaged to have a lid that includes silicon, acrylic and/or glass, and this lid may perform particular functions such as protecting one or more components of the MEMS device and/or providing sealing.

In at least one type of MEMS device, a lid provides a hermetic seal around one or more components of the device. Additionally, one or more pads may be formed externally from the sealed portion and may provide the capability to communicate with one or more components contained in the sealed portion. Devices such as these are typically formed to have components ranging in size from 1-100 micrometers (μm). Due at least in part to the relatively small size of these devices and components, multiple devices may be formed on a single wafer, such as 40-80 devices being formed on a wafer. After one or more devices are at least partially formed, typically one or more singulation processes may be utilized to singulate multiple devices formed on a wafer into individual MEMS devices.

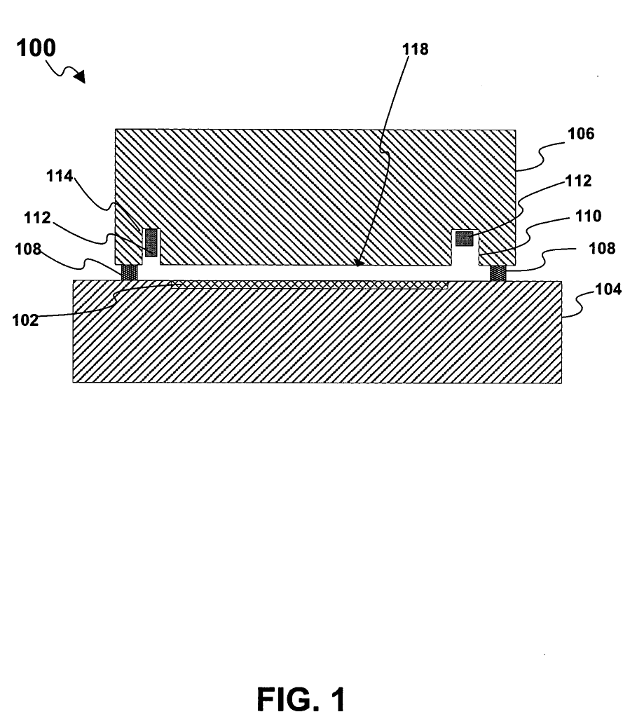

Illustrated in FIG. 1 is a sectional cut-away view of a MEMS device package 100. MEMS device package 100 includes one or more MEMS devices 102, which may include packaged electrical and/or mechanical devices. MEMS device 102 may include optical sensors, pressure sensors, and/or one or more other types of electrical and/or mechanical components. MEMS device 102 is formed on a substrate 104, which may comprise glass or silicon, but may also be formed using any material suitable for use as a substrate in an electronic device. Substrate 104 may alternatively be referred to as a silicon die, if the substrate includes silicon.

Formed on substrate 104 are one or more seals 108. Seals 108 may provide coupling between substrate 104 and lid 106, for example, and may provide a seal, such as a hermetic seal, such that MEMS device 102 is hermetically sealed in cavity 118. In one embodiment, seals 108 may include a bond ring, which may include a substantially continuous ring formed around MEMS device 102 and/or cavity 118, for example. In one embodiment, seals 108 may include one or more types of materials suitable for forming a seal, such as gold tin (AuSn) and/or silicon dioxide (SiO2), or any material or combination of materials that provide sealing and/or coupling functions.

Package 100 includes a lid 106 that may be formed from glass, acrylic and/or silicon. Lid 106 may be at least partially optically transparent, such as if the MEMS device 102 includes one or more optical components. Lid 106 may be formed to have one or more features, including cavity 110 and cavity 114. Cavities 110 and 114 may be configured such that one or more materials such as a getter and/or desiccant material 112 is disposed therein. A getter and/or desiccant material may include Hi-Cap 2000 and/or Hi-Cap 2100, available from Cookson Electronics, Inc., for example. Alternatively, one or more additional cavities and/or features may be formed in lid 106, such as one or more trenches. Formation of package 100, and/or one or more of the components of package 100 such as lid 106 may include one or more operations. In at least one embodiment, multiple MEMS devices may be formed on a substrate, may be provided with a lid, and may subsequently be singulated after being substantially formed into MEMS packages. In this context, singulated refers generally to one or more processes resulting in the physical separation of a coupled plurality of devices into individual devices.

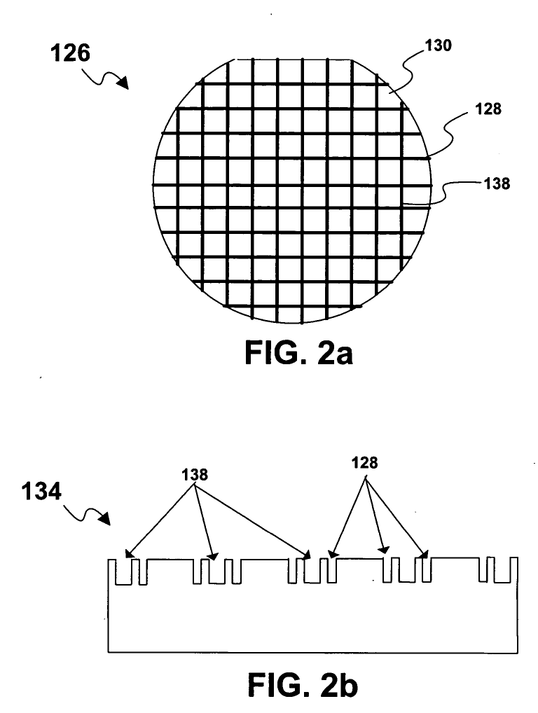

A method for forming a device such as a MEMS device package includes forming multiple MEMS devices on a single substrate, such as on a wafer, providing a lid for the multiple MEMS devices, and singulating the multiple MEMS devices with lids into multiple MEMS device packages. Formation of a lid for a MEMS device may involve one or more processes, such as micro-blasting, such that one or more features may be formed, as illustrated by lid 106 of FIG. 1. Micro-blasting, as used in this context, refers generally to an operation wherein an abrasive medium is ejected from a device having one or more nozzles, resulting-in the removal of at least a portion of the device being blasted. Micro-blasting may include sand-blasting, powder blasting, and/or liquid blasting, which may be performed with or without a slurry mix. The features that may be formed in a lid include cavities and trenches. Formation of features such as these may be better understood in reference to FIGS. 2a and 2b, and as explained in more detail herein.

Referring now to FIG. 2a, there is illustrated a non-singulated lid 126, which may include a wafer of silicon, glass and/or acrylic. Other embodiments may utilize a material in a wafer configuration, or formed from one or more types of materials in varying configurations, such as in a substantially rectangular configuration. However, in the embodiment of FIG. 2A, lid 126 is formed to have a substantially similar shape as a wafer (not shown). A plurality of MEMS devices may be formed, such as 40-80 MEMS devices, wherein the MEMS devices have dimensions of approximately 1500 μm×1500 μm, although other embodiments of the invention may include MEMS devices having dimensions outside this range. Lid 126 may include one or more lid portions 130, that may include lids of MEMS device packages, such as when assembled and/or singulated in one or more later operations. Lid 126 may have a plurality of features 128 and 138 formed thereon. In one embodiment, features 128 include cavities 110 and/or 114 of FIG. 1. Features 138 may include a trench that may be formed between lid portions 130. A trench in at least one embodiment, may include a guide and/or a pattern for singulation, and may include areas of a lid, in which at least a portion of the material is selectively removed, such as by micro-blasting.

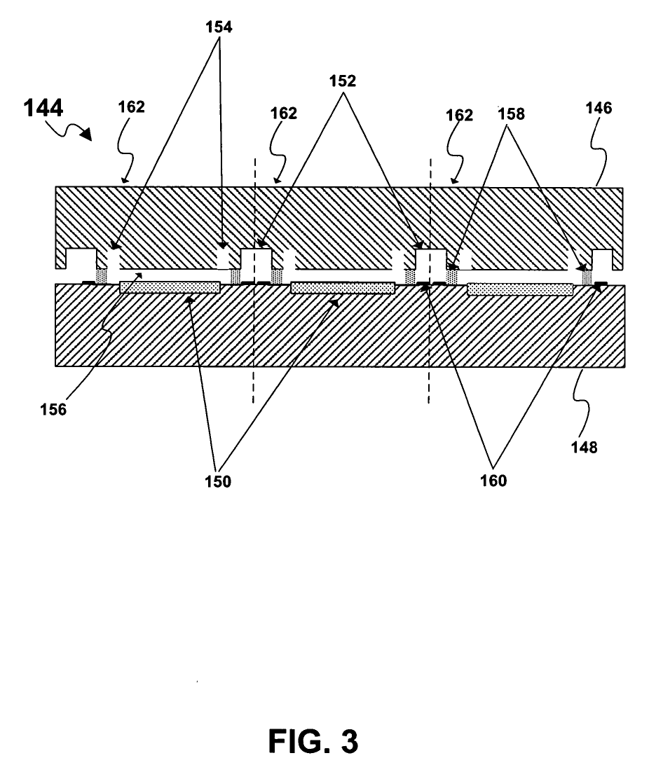

In operation, a trench may include areas that may be cut, such as by a saw, such that one or more lid portions 130 may be singulated. In at least one embodiment, singulation is not performed until after the lid portions are assembled into non-singulated MEMS device packages, such as illustrated in FIG. 3, and as explained in more detail later. Referring now to FIG. 2b, there is illustrated a sectional cut-away view of a portion of a lid 134, which may be a portion of wafer 126. As can be seen in more detail in FIG. 2b, wafer portion 134 has a plurality of features formed thereon, such as trenches 138 and/or cavities 128, for example. In at least one embodiment, cavities 128 include getter cavities. These features may provide particular functionality that may be better understood in reference to FIG. 3, and as explained in more detail herein.

Referring now to FIG. 3, there is illustrated a sectional cut-away view of a plurality of non-singulated MEMS device packages (144), comprising a lid 146, which may include multiple lid portions 162, and may be bonded to a substrate 148 by way of seals 158. Formed on substrate 148 is a plurality of MEMS devices 150. MEMS devices 150 may additionally be coupled to contact and/or bond pads 160, which may provide the capability to communicate with one or more portions of MEMS devices 150, such as when the MEMS devices are singulated. Seals 158 may include bond rings, for example, such as AuSn and/or SiO2 rings, and may provide hermetic sealing of MEMS devices 150 into cavities 156.

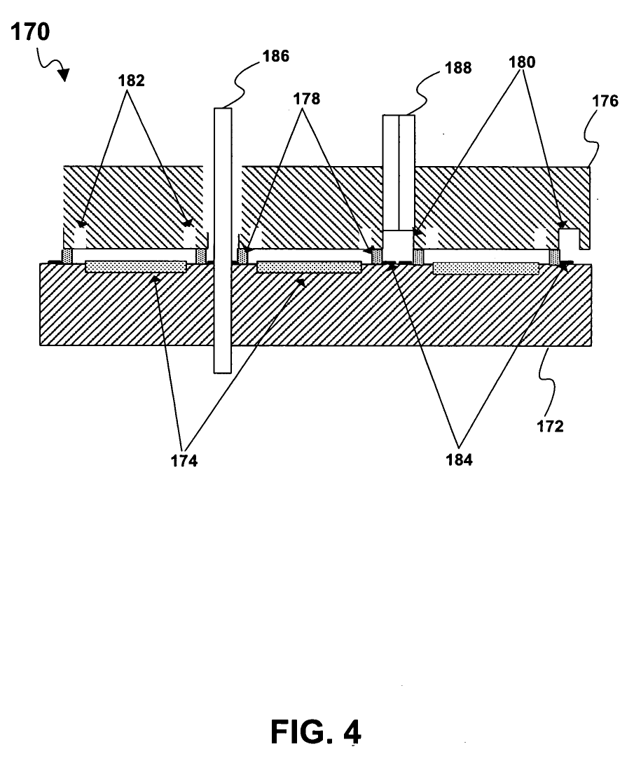

As illustrated in FIG. 3, one or more features may be formed in lid 146 and/or lid portions 162, including cavities 154, which may include getter and/or desiccant cavities, and/or trenches 152. Trenches 152 provide particular functionality during one or more singulation processes, such as by providing guides for sawing, which may reduce and/or eliminate the production of debris, and/or may reduce and/or eliminate physical damage to one or more portions of one or more MEMS device packages, as just an example. In at least one embodiment, substrate 148 is a silicon wafer, and lid 146 is silicon, glass and/or acrylic. Lid 146 may include multiple lid portions, and may substantially be of the same shape as wafer 148, such as illustrated in FIG. 2a. Features such as trenches may provide the capability to singulate the substrate and/or lid portions into multiple MEMS packages. However, particular functionality of features including trenches 152 may be better understood in reference to FIG. 4, and as explained in more detail herein.

Referring now to FIG. 4, there is illustrated one embodiment of a singulation operation, which may be performed on a plurality of non-singulated MEMS devices, such as non-singulated MEMS devices 144 of FIG. 3. Illustrated in FIG. 4 is a plurality of non-singulated MEMS device packages 170. MEMS device packages 170 may include MEMS devices 174 formed on a substrate 172, which may include a silicon wafer. One or more pads 184 may provide communication with one or more portions of MEMS devices 174. One or more seals 178 may seal a lid 176 to at least a portion of substrate 172. One or more features may be formed in lid 172, including cavities 182 and/or trenches 180.

As illustrated in FIG. 4, one or more saws 186 and/or 188 may singulate one or more MEMS device packages, such as by sawing 172 between packages and/or by sawing at least partially through a trench. However, although described as one or more sawing operations, one or more alternative operations may be utilized to singulate one or more MEMS device packages, such drilling, milling, water jetting, laser cutting and/or etching. However, continuing with this particular embodiment, singulation may include two or more sawing operations. In this embodiment, a double saw blade 188 may remove at least a portion of lid 176, such as by sawing from the top of lid 176 to the trench portion 180, for example, resulting in the lid 176 being divided into one or more lid portions. Subsequently, a single saw blade 186 may saw though at least a portion of substrate 172, for example, such as in the vicinity of where the trench was formed, between bond pads 184, resulting in the singulation of one or more of the MEMS device packages 170.

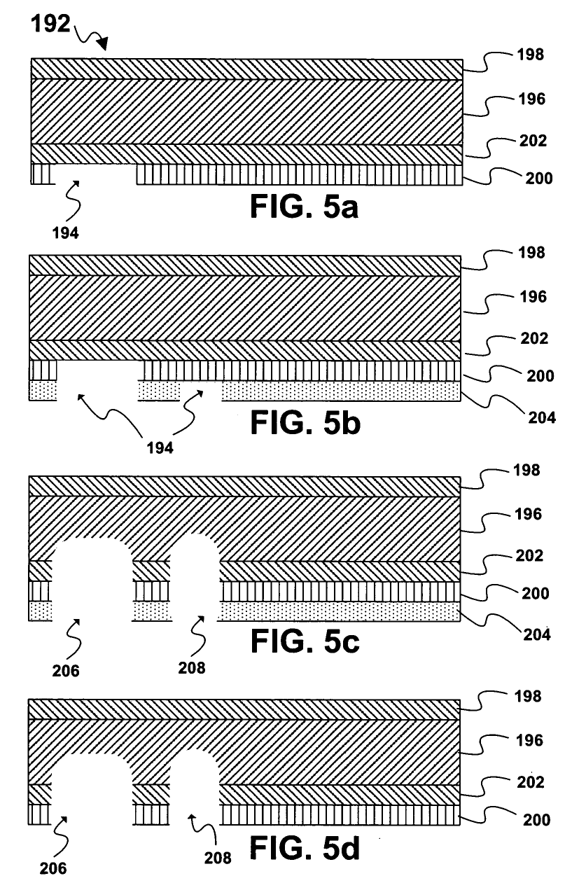

Referring now to FIG. 5, there is illustrated one embodiment of a method to form an electronic device. Illustrated in FIG. 5 are multiple stages 5a-5d of formation of features in a lid, such as a lid as illustrated in one or more of the foregoing figures, for example. Illustrated in FIG. 5a is lid 192. Lid 192 may include multiple layers. Layer 196 may include glass, plastic, and/or acrylic. Formed on layer 196 is a protective layer 198, which may include a layer of photoresist material, such as MegapoSit™ SPR3625 photoresist, available from Shipley Company. Formed on an opposite surface of layer 196, is a material layer 202, which may include a layer of silicon dioxide, which may also be referred to as TEOS. Formed on at least a portion of layer 202 is a second protection layer 200, which may include a layer of photoresist, as described previously. As illustrated in FIG. 5a, a portion of protection layer 200 may be selectively removed, such that a portion of an underlying layer may be exposed, such as portion 194.

Illustrated in FIG. 5b is a subsequent stage of formation of a lid. As illustrated by FIG. 5b, material layer 204 is formed on at least a portion of lid 192, such as on a portion of second protective layer 200. Material layer 204 may include a layer of urethane, for example. Additionally, one or more other materials may be formed on lid 192, such as a layer of water-soluble coating. These materials may provide masking and/or protective functions for one or more other layers during one or more micro-blasting processes, or assist in the removal of material layer 204.

In at least one embodiment, material layer 204 is at least partially photosensitive, and a portion of material layer 204 is developed and/or photo-etched, for example, such as portions 194. Additionally, depending at least in part on the particular photo-etching processes and/or materials, at least a portion of material layer 200 and/or material layer 202 are exposed, such as after one or more photo-etching processes. However, other embodiments may not use a photo-etching process. However, in this embodiment, exposing portions 194 may result in the formation of features with varying dimensions, such as varying depths, by use of one or more micro-blasting processes, as explained in more detail herein.

Continuing with this embodiment, referring now to FIG. 5c, at least a portion of lid 192 is removed, such as by one or more micro-blasting operations. In at least one embodiment, micro-blasting is performed on a substantial portion of the lid 192, and material layer 204 provides masking and/or protection to underlying layers, resulting in exposed portions of lid 192 not provided with material layer 204 being at least partially removed. This may result in the formation of one or more features, such as features 206 and/or 208 and, in at least one embodiment, features with varying characteristics, such as varying depths, may be formed by use of one or more micro-blasting operations. In at least one embodiment, features 206 and/or 208 include one or more cavities, such as getter cavities, and/or may include one or more trenches.

Referring now to FIG. 5d, after the formation of one or more features, such as features 206 and/or 208, at least a portion of layer 204 is removed. This may include one or more stripping operations, and may be performed by applying one or more materials to layer 204, which results in the dissolving and/or removal of at least a portion of layer 204. However, in other embodiments, layer 204 is not removed and additional removal processes are performed, such a grinding process. In this embodiment, at least a portion of lid 192 is additionally cleaned. This includes one or more washing processes, and results in the removal of one or more portions of layer 204, and/or debris formed by one or more micro-blasting operations.

Additionally, although not illustrated in detail, the micro-blast process may be repeated one or more times. This may result in the formation of additional features of varying depth or can result in the selective deepening of some cavities while the depths of other cavities are unchanged.

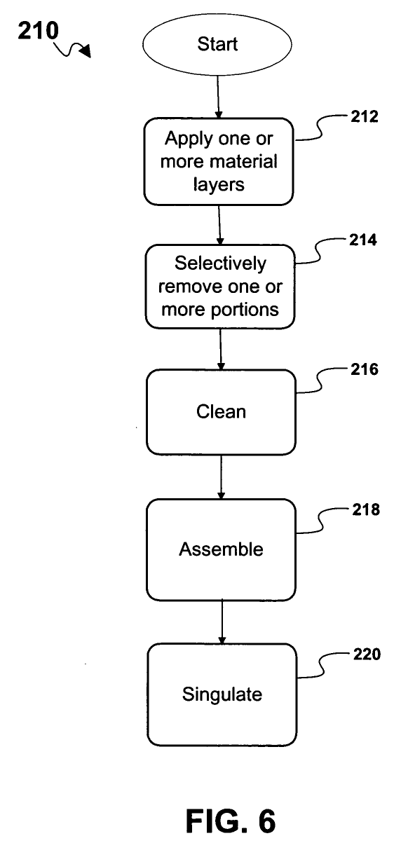

Formation of one or more portions of a MEMS device package such as illustrated in one or more of the aforementioned figures may include one or more processes, and/or numerous process operations. Particular methods of formation of the devices and/or portions of device packages illustrated herein may be better understood when explained with reference to FIG. 6, below.

Referring now to FIG. 6, one embodiment of a technique for forming at least a portion of a MEMS device package is illustrated by a flowchart. Such an embodiment may be employed to at least partially form a MEMS device package, as described below. The flowchart illustrated in FIG. 6 may be used to form a device at least in part, such as one or more of the devices illustrated in one or more of the foregoing figures. Intervening blocks not shown may be employed without departing from the scope of claimed subject matter.

Flowchart 210 depicted in FIG. 6 may, in other embodiments, be implemented in software, hardware and/or firmware, such as in a computer controlled formation system. The method begins at block 212, in which one or more material layers are applied to a lid, such as a lid comprising glass, plastic and/or acrylic. At block 214, one or more portions of the lid, such as one or more portions of one or more of the layer applied at block 212 are selectively removed, and one or more features are at least partially formed. At block 216, one or more portions of the lid are cleaned, such as by stripping at least a portion of one or more layers, and/or washing at least a portion of the lid. At block 218, the lid is at least partially assembled into one or more non-singulated devices, such as MEMS device packages. At block 220, one or more non-singulated MEMS device packages is singulated, such as by singulating with one or more saws that saws in the vicinity of one or more of the features formed at block 212.

At block 212, application of one or more material layers to a lid includes applying one or more protective layers to a lid that may comprise glass, plastic and/or acrylic such as illustrated in FIGS. 5a and/or 5. In at least one embodiment, one or more protective layers may be applied to a lid, and may include a layer of photoresist material, such as MegapoSit™ SPR3625 photoresist, and additionally, one or more materials substantially comprising TEOS and/or a protective material including urethane and water soluble coating may be applied to the lid. Application of one or more material layers may depend at least in part on the materials applied, and one or more deposition, spraying, spin-coating, dipping, and/or spreading processes may be utilized to form one or more material layers, such as one or more of the layers illustrated in FIGS. 5a and/or 5b.

At block 214, selective removal of one or more portions of a lid, such as one or more portions of one or more materials applied at block 212, may include one or more removal processes, such as one or more etching and/or micro-blasting processes. In at least one embodiment, a portion of one or more material layers is removed by an etching process, and one or more micro-blasting processes is used to selectively remove additional portions of the material. This results in the at least partial formation of features in the lid, such as one or more cavities and/or trenches, such as illustrated in FIG. 5c. In this embodiment, a layer of photosensitive material, such as photosensitive urethane, is applied to a lid. At least a portion of the photosensitive urethane material is removed by use of one or more photo-etching processes, and one or more portions of a lid is at least partially exposed by the removal of the photosensitive material. One or more micro-blasting processes, such as one or more powder-blasting processes, is utilized to selectively remove one or more additional portions of a lid, such as one or more portions of a lid exposed by the removal of the photosensitive material. In at least one embodiment, one or more cavities, such as one or more getter cavities and/or desiccant cavities, and one or more trenches may be formed.

At block 216, one or more portions of the lid are cleaned. This may include removing at least a portion of one or more material layers, such by stripping, for example, and/or washing at least a portion of the lid, resulting in the removal of debris. The debris may be formed from one or more micro-blasting processes. In at least one embodiment, a lid may have a material layer substantially comprising urethane, and at least a portion of the urethane layer may be stripped, such as by dissolving at least a portion of the urethane by the application of another material. Additionally, one or more micro-blasting processes may produce debris, and one or more washing processes may result in the removal of at least a portion of the debris.

At block 218, the lid may be at least partially assembled into one or more non-singulated devices, such as a plurality of non-singulated MEMS device packages. In this embodiment, the lid may be coupled with one or more MEMS devices, such as one or more MEMS devices formed on a substrate and may be coupled by use of one or more bond rings. The bond ring may be capable of providing a hermetic seal around a MEMS device, for example. In this embodiment, a wafer of silicon may have a plurality of MEMS devices formed thereon, and the lid formed by one or more of the foregoing processes may be coupled with the wafer.

At block 220, the assembled non-singulated devices may be at least partially singulated. In at least one embodiment, wherein one or more trenches were formed at block 214, singulation includes a sawing operation, wherein one or more saws saw at least partially through one or more trenched portions of the lid, such as illustrated in FIG. 4. For example, one or more laser cutting, etc processes may be utilized to singulate one or more of the devices. Thus, a MEMS device package may be formed, wherein the MEMS device package includes a lid that is at least partially trenched, such as by use of one or more micro-blasting operations. In one embodiment, formation of a MEMS device package in accordance with one or more of the foregoing blocks may result in the formation of a device wherein the formation of debris may be reduced and/or eliminated. Damage to one or more layers, such as by scratching, pitting, chipping, and/or the production of stress concentrations is also reduced and/or eliminated, and/or a feature having particular characteristics, such as varying depths, is formed by a reduced number of process operations, such as by forming multiple features with varying depths by use of a micro-blasting process.

It is, of course, now appreciated, based at least in part on the foregoing disclosure, that software may be produced capable of performing a variety of operations, including one or more of the foregoing operations. It will also be understood that, although particular embodiments have been described, claimed subject matter is not limited in scope to a particular embodiment or implementation. For example, one embodiment may be in hardware, such as implemented to operate on a device or combination of devices as previously described, whereas another embodiment may be in software. Likewise, an embodiment may be implemented in firmware, or as any combination of hardware, software, and/or firmware. Additionally, one embodiment may include storage media such as, one or more CD-ROMs and/or disks, for example, may have stored thereon instructions, that when executed by a computer result in an embodiment of a method in accordance with claimed subject matter, such as one of the embodiments previously described.

In the preceding description, various aspects of claimed subject matter have been described. For purposes of explanation, specific numbers, systems and/or configurations were set forth to provide a thorough understanding of claimed subject matter. However, it should be apparent to one skilled in the art having the benefit of this disclosure that claimed subject matter may be practiced without the specific details. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes as fall within the true spirit of claimed subject matter.

1. An electronic device, comprising:
a substrate;
at least one electronic component formed on the substrate;
a lid coupled to the substrate, wherein the lid at least partially covers said at least one electronic component, and wherein said lid is at least partially trenched by use of one or more micro-blasting processes.

2. The electronic device of claim 1, wherein said electronic device comprises a micro-electro-mechanical system (MEMS) device package.

3. The electronic device of claim 1, wherein said lid has one or more cavities formed thereon, wherein at least a portion of said one or more cavities are formed by use of one or more micro-blasting processes.

4. The electronic device of claim 1, wherein said micro-blasting processes is selected from one or more of the group consisting of: sand-blasting, powder-blasting and liquid-blasting.

5. The electronic device of claim 1, wherein said substrate comprises at least a portion of a silicon wafer.

6. (canceled)

7. The electronic device of claim 2, wherein said MEMS device is selected from one or more of the group consisting of: light engines, actuators, pressure sensors and optical detectors.

8. The electronic device of claim 1, wherein said lid is at least partially optically transparent.

9. The electronic device of claim 8, wherein said lid is selected from one or more of the group consisting of: silicon, glass, and acrylic.

10. An electronic device, comprising:
means for forming a substrate, wherein said substrate has at least one electronic component formed thereon;
means for forming a lid, wherein said lid is at least partially trenched by use of one or more micro-blasting processes; and
means for sealing said one or more electronic components by use of said lid.

11. The electronic device of claim 10, wherein said electronic device comprises a micro-electro-mechanical system (MEMS) device package.

12. The electronic device of claim 10, wherein said micro-blasting processes is selected from one or more of the group consisting of: sand-blasting, powder-blasting and liquid-blasting.

13. The electronic device of claim 10, wherein said seal comprises a hermetic seal.

14. (canceled)

15. The electronic device of claim 11, wherein said MEMS device is selected from one or more of the group consisting of: light engines, actuators, pressure sensors and optical detectors.

16. The electronic device of claim 10, wherein said lid is at least partially optically transparent, and is selected from one or more of the group consisting of comprises one or more of: glass, plastic, and acrylic.

17. A method comprising:
applying one or more materials to a non-singulated micro-electro-mechanical systems (MEMS) lid to form at least one mask;
selectively removing one or more portions of the mask; and
micro-blasting at least a portion of the non-singulated MEMS lid to form one or more trenches.

18. The method of claim 17, and further comprising:
coupling the lid to a substrate, wherein the substrate has one or more electronic components formed thereon; and
singulating the lid and substrate into one or more packaged MEMS devices, wherein said singulation is performed in the vicinity of the one or more trenches.

19. The method of claim 17, wherein said lid is at least partially optically transparent, and is selected from one or more of the group consisting of: glass, plastic, and acrylic.

20. The method of claim 17, wherein one or more materials is selected from one or more of the group consisting of: silicon dioxide, urethane, and photoresist material.

21. The method of claim 20, wherein said mask substantially comprises photosensitive urethane.

22. The method of claim 17, wherein said micro-blasting is selected from one or more of the group consisting of: sand-blasting, powder-blasting and liquid-blasting.

23. The method of claim 17, and further comprising micro-blasting at least a portion of the lid to form one or more additional features.

24. The method of claim 23, wherein said one or more additional features is selected from one or more of the group consisting of: trenches, including trenches, and cavities.

25. The method of claim 17, wherein said coupling is performed by one or more seals.

26. The method of claim 25, wherein said one or more seals comprise bond rings.

27. The method of claim 17, wherein said one or more packaged MEMS devices is selected from one or more of the group consisting of: light engines, actuators, pressure sensors and optical detectors.

28. A micro-electro-mechanical system (MEMS) device package, formed substantially by a process comprising:
applying one or more materials to a non-singulated MEMS lid to form at least one mask;
selectively removing one or more portions of the mask;
micro-blasting at least a portion of the non-singulated MEMS lid to form one or more trenches
coupling the non-singulated MEMS lid to a substrate, wherein the substrate has one or more MEMS devices formed thereon; and
singulating the lid and substrate into one or more packaged MEMS devices, wherein said singulation is performed in the vicinity of the one or more of formed features.

29. The MEMS device package of claim 28, wherein said lid is at least partially optically transparent, and is selected from one or more of the group consisting of: glass, plastic, and acrylic.

30. The MEMS device package of claim 28, wherein the one or more materials is selected from one or more of the group consisting of: silicon dioxide, urethane, and photoresist material.

31. The MEMS device package of claim 28, wherein said mask substantially comprises photosensitive urethane.

32. The MEMS device package of claim 28, wherein said selective removal comprises one or more micro-blasting processes.

33. The MEMS device package of claim 28, wherein said one or more micro-blasting processes is selected from one or more of the group consisting of: sand-blasting, powder-blasting and liquid-blasting.

34. The MEMS device package of claim 28, and further comprising micro-blasting at least a portion of the lid to form one or more additional features.

35. The MEMS device package of claim 34, wherein said one or more additional features is selected from one or more of the group consisting of: trenches, including trenches, and cavities.

36. The MEMS device package of claim 28, wherein said coupling is performed by use of one or more seals.

37. The MEMS device package of claim 28, wherein said one or more seals comprise bond rings.

38. The MEMS device package of claim 28, wherein said MEMS device packages is selected from one or more of the group consisting of: light engines, actuators, pressure sensors and optical detectors.
